(19) United States
(12) Patent Application Publication
(10) Pub. No.: US 2023/0407477 A1
(43) Pub. Date: Dec. 21, 2023

(54) SUBSTRATE PROCESSING APPARATUS INCLUDING IMPROVED EXHAUST STRUCTURE

(71) Applicant: ASM IP Holding B.V., Almeree (NL)

(72) Inventor: Wei Chen Liao, Tokyo (JP)

(21) Appl. No.: 18/209,659

(22) Filed: Jun. 14, 2023

Related U.S. Application Data
(60) Provisional application No. 63/353,118, filed on Jun. 17, 2022.

(51) Int. Cl. C23C 16/455

(52) U.S. Cl. CPC C23C 16/45553; C23C 16/45565; C23C 16/4558; C23C 16/45536; C23C 16/45551

(57) ABSTRACT

A substrate processing apparatus unit is disclosed. Exemplary substrate processing apparatus includes a reaction chamber provided with a reaction space; a susceptor disposed in the reaction chamber and configured to support a substrate, wherein the susceptor is configured to be vertically movable between a process position and a transfer position; a shower plate provided above the susceptor and configured to provide the reaction space with a gas; a gas exhaust unit configured to exhaust the gas from the reaction chamber, comprising: an exhaust duct surrounds the shower plate and provided with a main duct; a first flow control ring that surrounds the susceptor with a space when the susceptor is in the process position; and a second flow control ring surrounds the first flow control ring; wherein a first exhaust channel is formed between the exhaust duct and the first flow control ring; wherein a second exhaust channel is formed between the first flow control ring and the second control ring, and the second exhaust channel is fluidly connected to the main duct and an area below the susceptor.

### CROSS-REFERENCE TO RELATED APPLICATIONS

This application claims priority to U.S. Provisional Patent Application Ser. No. 63/353,118 filed Jun. 17, 2022 titled SUBSTRATE PROCESSING APPARATUS INCLUDING IMPROVED EXHAUST STRUCTURE, the disclosure of which is hereby incorporated by reference in its entirety.

### FIELD OF INVENTION

The present disclosure relates generally to a substrate processing apparatus including an improved exhaust structure.

### BACKGROUND OF THE DISCLOSURE

FIG. 1a is a schematic cross-sectional view of a prior substrate processing apparatus showing a deposition step. In the substrate processing apparatus, a reaction gas is introduced into a reaction space 11 of a reaction chamber 10 through a shower plate 12. The reaction gas is exhausted to the outside through an exhaust duct 77. However, some of the reaction gas is introduced into an area below a susceptor 16 during a deposition step.

FIG. 1B is a schematic cross-sectional view of a prior substrate processing apparatus showing a treatment step. The reaction gas may diffuse back to the reaction space 11 during a treatment step, resulting in increasing an edge film thickness on a substrate 15.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a substrate processing apparatus is provided. The substrate processing apparatus comprises a reaction chamber provided with a reaction space; a susceptor disposed in the reaction chamber and configured to support a substrate, wherein the susceptor is configured to be vertically movable between a process position and a transfer position; a shower plate provided above the susceptor and configured to provide the reaction space with a gas; a gas exhaust unit configured to exhaust the gas from the reaction chamber, comprising: an exhaust duct surrounds the shower plate and provided with a main duct; a first flow control ring that surrounds the susceptor with a space when the susceptor is in the process position; and a second flow control ring surrounds the first flow control ring; wherein a first exhaust channel is formed between the exhaust duct and the first flow control ring; wherein a second exhaust channel is formed between the first flow control ring and the second control ring, and the second exhaust channel is fluidly connected to the main duct and an area below the susceptor.

In various embodiments, the first gas flow control ring may further comprise a plurality of protrusions configured to engage with an inner circumference of the second flow control ring.

In various embodiments, the space may be 0.5 to 2.5 mm.

In various embodiments, the size of the first exhaust channel may be 0.5 to 2.5 mm.

In various embodiments, the size of the second exhaust channel may be 0.5 to 2.5 mm.

In various embodiments, the gas may comprise a precursor gas, a reactant gas, and a first inert gas.

In various embodiments, the precursor gas may comprise at least one of: bis(diethylamino)silane (BDEAS), tetrakis(dimethylamino)silane (4DMAS), tris(dimethylamino)silane (3DMAS), bis(dimethylamino)silane (2DMAS), tetrakis(ethylmethylamino)silane (4EMAS), tris(ethylmethylamino)silane (3EMAS), bis(tertiary-butylamino)silane (BTBAS), and bis(ethylmethylamino)silane (BEMAS), Diisopropylamino silane (DIPAS) and combination thereof.

In various embodiments, the reactant gas may comprise at least one of: O2, N2O, CO2, and combination thereof.

In various embodiments, the first inert may comprise at least one of: He, Ar, N2, and combination thereof.

In various embodiments, a second inert gas may be configured to provide from an area below the susceptor to above the susceptor and the main duct through the space and the second exhaust channel.

In various embodiments, the substrate processing apparatus may comprise plasma enhanced atomic layer deposition apparatus.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1a is a schematic cross-sectional view of a prior substrate processing apparatus showing a deposition step.

FIG. 1B is a schematic cross-sectional view of a prior substrate processing apparatus showing a treatment step.

FIG. 2 is a schematic diagram of a substrate processing apparatus in an embodiment of the present invention.

FIG. 3 is a timing sequence of a method in an embodiment of the present invention.

FIG. 4 is a schematic cross-sectional view of a substrate processing apparatus in an embodiment of the present invention.

FIG. 5 is a schematic perspective view of a first flow control ring in an embodiment of the present invention.

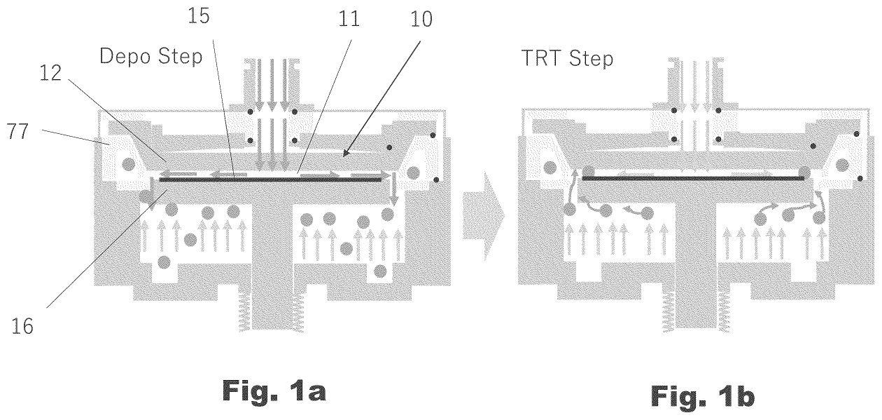

It will be appreciated that elements in the figures are illustrated for simplicity and clarity and have not necessarily been drawn to scale. For example, the dimensions of some of the elements in the figures may be exaggerated relative to other elements to help understanding of illustrated embodiments of the present disclosure.

### DETAILED DESCRIPTION OF EXEMPLARY EMBODIMENTS

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

In this disclosure, “gas” may include material that is a gas at normal temperature and pressure, a vaporized solid and/or a vaporized liquid, and may be constituted by a single gas or a mixture of gases, depending on the context. A gas other than the process gas, i.e., a gas introduced without passing through a gas supply unit, such as a shower plate, or the like, may be used for, e.g., sealing the reaction space, and may include a seal gas, such as a rare or other inert gas. The term inert gas refers to a gas that does not take part in a chemical reaction to an appreciable extent and/or a gas that can excite a precursor when plasma power is applied.

As used herein, the term “substrate” may refer to any underlying material or materials that may be used, or upon which, a device, a circuit, or a film may be formed.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

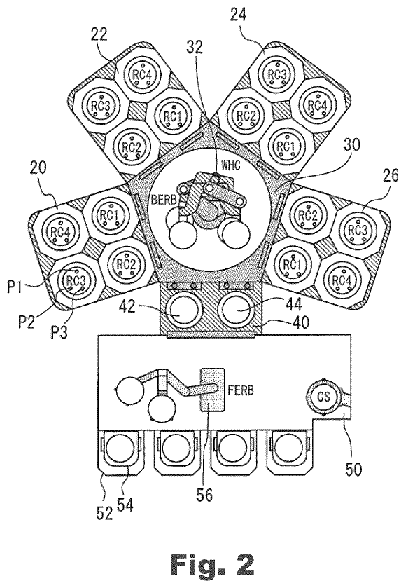

FIG. 2 is a schematic plan view of a substrate processing apparatus in an embodiment of the present invention. The substrate processing apparatus may comprise: (i) four process modules 20, 22, 24, 26, each having four reaction chambers RC1, RC2, RC3, RC4; (ii) a substrate handling chamber 30 including two back end robots 32 (substrate handling robots); and (iii) a load lock chamber 40 for loading or unloading two substrates simultaneously, the load lock chamber 40 being attached to the one additional side of the substrate handling chamber 30, wherein each back end robot 32 is accessible to the load lock chamber 40. Each of the back end robots 32 have at least two end-effectors accessible to the two reaction chambers of each unit simultaneously, said substrate handling chamber 30 having a polygonal shape having four sides corresponding to and being attached to the four process modules 20, 22, 24, 26, respectively, and one additional side for a load lock chamber 40, all the sides being disposed on the same plane. The interior of each process modules 20, 22, 24, 26 and the interior of the load lock chamber 40 may be isolated from the interior of the substrate handling chamber 30 by a gate valve.

In some embodiments, a controller (not shown) may store software programmed to execute sequences of substrate transfer, for example. The controller may also: check the status of each process chamber; position substrates in each process chamber using sensing systems, control a gas box, and an electric box for each module; control a front-end robot 56 in an equipment front end module based on a distribution status of substrates stored in FOUP 52 and the load lock chamber 40; control the back end robots 32; and the control gate valves and other valves.

A skilled artisan may appreciate that the apparatus includes one or more controller(s) programmed or otherwise configured to cause the deposition and reactor cleaning processes described elsewhere herein to be conducted. The controller(s) may communicate with the various power sources, heating systems, pumps, robotics, gas flow controllers, or valves, as will be appreciated by the skilled artisan.

In some embodiments, the apparatus may have any number of reaction chambers and process modules greater than one (e.g., 2, 3, 4, 5, 6, or 7). In FIG. 2, the apparatus has sixteen reaction chambers, but it may have 8 or more. Typically, the reaction chambers may comprise plasma reactors for depositing a thin film or layer on a wafer. In some embodiments, all the modules may have identical capabilities for treating wafers so that the unloading/loading can sequentially and regularly be timed, thereby increasing productivity or throughput. In some embodiments, the modules may have different capabilities (e.g., different treatments) but their handling times may be substantially identical.

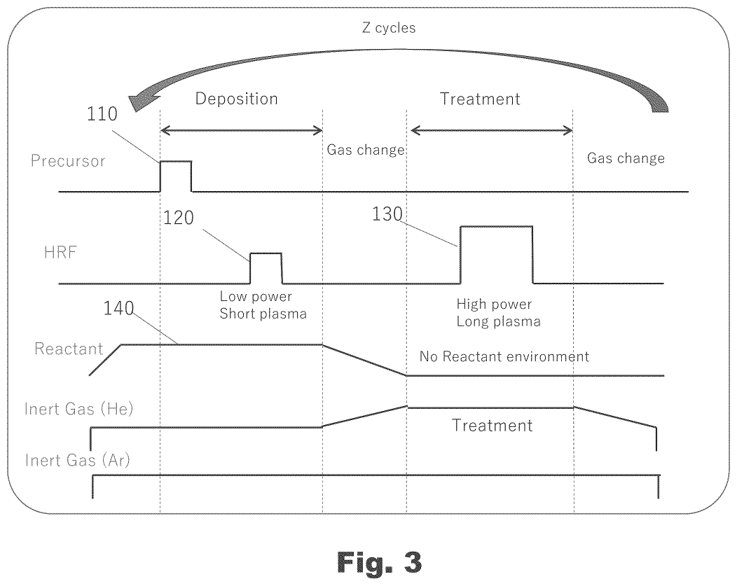

FIG. 3 is a timing sequence of a method in an embodiment of the present invention. As illustrated, an inert gas may be provided to a reaction chamber continuously through one or more precursor gas pulses 110, one or more reactant gas pulse 140, and/or one or more plasma power pulses 120, 130. During the deposition step and the treatment step, the reactant gas and/or inert gas may be exposed to a (e.g., direct) plasma to form excited species for use in, e.g., a PEALD (Plasma Enhanced Atomic Layer Deposition) process. The deposition cycle and the treatment cycle can be repeated. A power to form the plasma during the treatment step may be higher than that during the deposition step.

The precursor gas may comprise at least one of: bis(diethylamino)silane (BDEAS), tetrakis(dimethylamino)silane (4DMAS), tris(dimethylamino)silane (3DMAS), bis(dimethylamino)silane (2DMAS), tetrakis(ethylmethylamino)silane (4EMAS), tris(ethylmethylamino)silane (3EMAS), bis(tertiary-butylamino)silane (BTBAS), and bis(ethylmethylamino)silane (BEMAS), Diisopropylamino silane (DIPAS), or combination thereof.

The reactant gas may comprise at least one of: O2, N2O, CO2, or combination thereof.

The first inert gas may comprise at least one of: He, Ar, N2, or combination thereof. The first inert gas may be used to ignite a plasma or facilitate ignition of the plasma within the reaction chamber, to purge reactants and/or byproducts from the reaction chamber, and/or be used as a carrier gas to assist with delivery of the precursor to the reaction chamber.

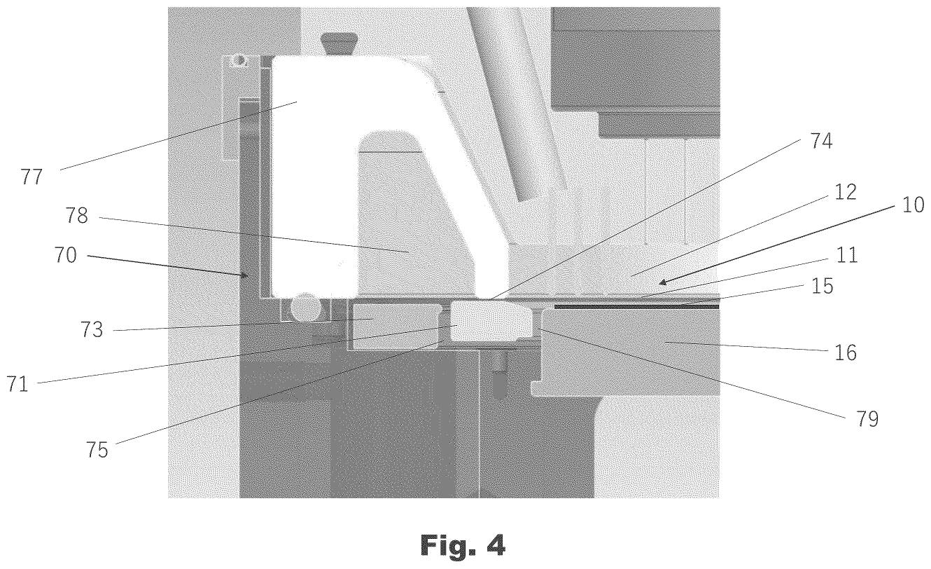

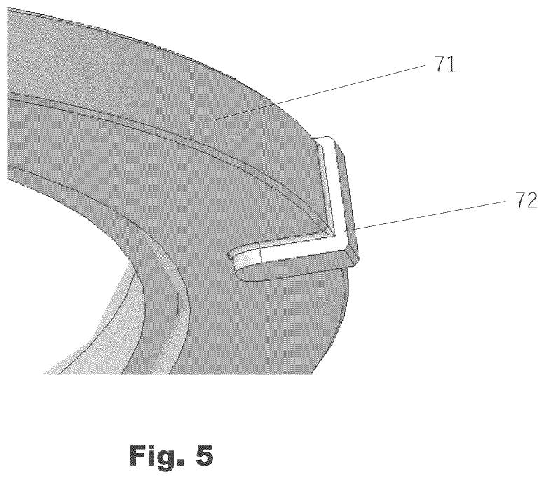

FIG. 4 is a schematic cross-sectional view of a substrate processing apparatus in an embodiment of the present invention. The substrate processing apparatus includes a reaction chamber 10 provided with a reaction space 11; a susceptor 16 disposed in the reaction chamber 10 and configured to support a substrate 15. The susceptor 16 is configured to be vertically movable between a process position and a transfer position. When the susceptor 16 is in the process position, the substrate processing apparatus may perform processing on the substrate 15. When the susceptor 16 is in the transfer position, the substrate processing apparatus may transfer the substrate 15 in and out of the reaction chamber 10.

The substrate processing apparatus further comprises a shower plate 12 provided above the susceptor 16 and configured to provide the reaction space 11 with the precursor gas, the reactant gas, and the first inert gas. The shower plate 12 may have gas holes. The shower plate 12 may be electrode for PEALD apparatus.

The substrate processing apparatus further comprises a gas exhaust unit 70 configured to exhaust the gases from the reaction chamber. The gas exhaust unit 70 comprises an exhaust duct 77 surrounds the shower plate 12 and provided with a main duct 78; a first flow control ring 71 that surrounds the susceptor 16 with a space 79 when the susceptor 16 is in the process position; and a second flow control ring 73 surrounds the first flow control ring 71. A first exhaust channel 74 is formed between the exhaust duct 77 and the first flow control ring 71. The gases are exhaust to the outside through the first exhaust channel 74 and the main duct 78. Some of the gases may be introduced into an area below the susceptor 16 during the deposition step.

A second exhaust channel 75 is formed between the first flow control ring 71 and the second control ring 73, and the second exhaust channel 75 is fluidly connected to the main duct 78 and an area below the susceptor 16. The gases below the susceptor 16 may be exhausted to the main duct 78 through the second exhaust channel 75 during the treatment step.

The first gas flow control ring 71 may further comprise a plurality of protrusions 72 configured to engage with an inner circumference of the second flow control ring 73, thereby having the second exhaust channel 75.

The space 79 between the first flow control ring 71 and the susceptor 16 may be 0.5 to 2.5 mm. The size of the first exhaust channel 74 may be 0.5 to 2.5 mm. The size of the second exhaust channel 75 may be 0.5 to 2.5 mm.

A second inert gas may be configured to provide from an area below the susceptor 16 to above the susceptor 16 and the main duct 78 through the space 75 and the second exhaust channel 75. The second inert gas may be seal gas and may comprise at least one of: He, Ar, N2, or combination thereof.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A substrate processing apparatus comprising:
a reaction chamber provided with a reaction space;
a susceptor disposed in the reaction chamber and configured to support a substrate,
wherein the susceptor is configured to be vertically movable between a process position and a transfer position;
a shower plate provided above the susceptor and configured to provide the reaction space with a gas;
a gas exhaust unit configured to exhaust the gas from the reaction chamber, comprising:
an exhaust duct surrounds the shower plate and provided with a main duct;
a first flow control ring that surrounds the susceptor with a space when the susceptor is in the process position; and
a second flow control ring surrounds the first flow control ring;
wherein a first exhaust channel is formed between the exhaust duct and the first flow control ring;
wherein a second exhaust channel is formed between the first flow control ring and the second control ring, and the second exhaust channel is fluidly connected to the main duct and an area below the susceptor.

2. The substrate processing apparatus according to claim 1, the first gas flow control ring further comprising a plurality of protrusions configured to engage with an inner circumference of the second flow control ring.

3. The substrate processing apparatus according to claim 1, wherein the space is 0.5 to 2.5 mm.

4. The substrate processing apparatus according to claim 1, wherein the size of the first exhaust channel is 0.5 to 2.5 mm.

5. The substrate processing apparatus according to claim 1, wherein the size of the second exhaust channel is 0.5 to 2.5 mm.

6. The substrate processing apparatus according to claim 1, wherein the gas comprises a precursor gas, a reactant gas, and a first inert gas.

7. The substrate processing apparatus according to claim 6, wherein the precursor gas comprises at least one of: bis(diethylamino)silane (BDEAS), tetrakis(dimethylamino)silane (4DMAS), tris(dimethylamino)silane (3DMAS), bis(dimethylamino)silane (2DMAS), tetrakis(ethylmethylamino)silane (4EMAS), tris(ethylmethylamino)silane (3EMAS), bis(tertiary-butylamino)silane (BTBAS), and bis(ethylmethylamino)silane (BEMAS), Diisopropylamino silane (DIPAS), or combination thereof.

8. The substrate processing apparatus according to claim 6, wherein the reactant gas comprises at least one of: O2, N2O, CO2, or combination thereof.

9. The substrate processing apparatus according to claim 6, wherein the first inert gas comprises at least one of: He, Ar, N2, or combination thereof.

10. The substrate processing apparatus according to claim 1, wherein a second inert gas is configured to provide from an area below the susceptor to above the susceptor and the main duct through the space and the second exhaust channel.

11. The substrate processing apparatus according to claim 1, wherein the substrate processing apparatus comprise plasma enhanced atomic layer deposition apparatus.
